(19) United States
(12) Patent Application Publication
(10) Pub. No.: US 2008/0237757 A1
(43) Pub. Date: Oct. 2, 2008

(54) MICRO MOVABLE DEVICE, WAFER, AND METHOD OF MANUFACTURING WAFER

(75) Inventors: Hiroaki INOUE, Kawasaki (JP); Takashi KATSUKI, Kawasaki (JP); Hiroshi ISHIKAWA, Kawasaki (JP); Fumihiko NAKAZAWA, Kawasaki (JP); Takayuki YAMAJI, Yokohama-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: FUJITSU LIMITED, Kawasaki-shi (JP); FUJITSU MEDIA DEVICES LIMITED, Yokohama-shi (JP)

(21) Appl. No.: 12/059,242

(22) Filed: Mar. 31, 2008

(30) Foreign Application Priority Data
Mar. 29, 2007 (JP) 2007-088911

(51) Int. Cl. H01L 29/84; H01L 21/02

(52) U.S. Cl. 257/415; 438/53; 257/E29.324; 257/E21.002

(57) ABSTRACT

A micro movable device is made by processing a material substrate of a multilayer structure including a first layer, a second layer having a finely rough region on its surface on the side of the first layer, and an intermediate layer provided between the first and the second layer. The micro movable device includes a first structure formed in the first layer and a second structure formed in the second layer. The second structure includes a portion opposing the first structure via a gap and having a finely rough region on the side of the first structure, and being relatively displaceable with respect to the first structure.

### BACKGROUND OF THE INVENTION

1. Field of the Invention

The present invention relates to a micro movable device produced by micromachining techniques. It also relates to a wafer used for manufacturing the micro movable device, and to a method of manufacturing the wafer.

2. Description of the Related Art

Recently, micromachined devices have been used for a wide variety of applications. Such devices include a micro-oscillation element that has a minute movable portion or oscillating portion, such as an angular speed sensor, an acceleration sensor, or a micromirror device. The angular speed sensor and the acceleration sensor are employed, for example, in a video camera or a mobile phone with camera for stabilizing an image against the user's hand motion, a car navigation system, an airbag release timing system, or a robot for controlling the posture thereof. The micromirror device serves to reflect light, for example in the field of optical disk technique or optical communication technique. Such micro movable device generally includes a stationary portion, a movable structure that can be displaced, and a link portion that connects the stationary portion and the movable structure. The micro movable device thus configured can be found, for example, in patent documents 1 to 3 listed below.
Patent document 1: JP-A-2003-19700
Patent document 2: JP-A-2004-341364
Patent document 3: JP-A-2006-72252

FIG. 13 depicts a micro movable device X2 which is an example of a conventional micro movable device. The micro movable device X2 includes a stationary portion 81 and a movable structure 82, and is designed to perform a predetermined function. The stationary portion 81 and the movable structure 82 are connected via a link portion not shown in FIG. 13. The movable structure 82 is provided so as to be displaced, for example, as indicated by an arrow D in FIG. 13.

FIG. 14 shows some of the manufacturing process of the micro movable device X2. To manufacture the micro movable device X2, first a material substrate 90 as shown in FIG. 14(a) is prepared. The material substrate 90 is what is known as a silicon-on-insulator (hereinafter, SOI) wafer, and has a multilayer structure including a silicon layer 91, a silicon layer 92, and an intermediate layer 93 provided therebetween. The thickness of the intermediate layer 93 is approximately 1 μm.

Then as shown in FIG. 14(b), an anisotropic dry etching process is performed over the silicon layer 91 via a predetermined mask, so as to form the portions to be provided on the silicon layer 91 (for example, a part of the stationary portion 81, the movable structure 82, and the link portion).

Another anisotropic dry etching process is performed over the silicon layer 92 via a predetermined mask, so as to form the portions to be provided on the silicon layer 92 (for example, a part of the stationary portion 81), as shown in FIG. 14(c).

Proceeding to FIG. 14(d), an isotropic etching process is performed over the intermediate layer 93, so as to remove the exposed portion thereof and the portion thereof located between the stationary portion 81 and the movable structure 82. Through a method including such process, the micro movable device X2 can be obtained.

In the micro movable device X2, the movable structure 82 can accidentally stick to the stationary portion 81 as shown in FIG. 15, after the etching process described above referring to FIG. 14(d), or during the operation of the device. Such sticking inhibits the movable structure 82 from being displaced, thereby causing the micro movable device X2 to fail to work normally.

To avoid such sticking, mainly a predetermined isotropic dry etching or isotropic wet etching process may be performed over the surface 81a of the stationary portion 81 opposing the movable structure 82, and the surface 82a of the movable structure 82 opposing the stationary portion 81, after the etching process described referring to FIG. 14(d), to roughen the surfaces 81a, 82a. Giving certain roughness to the surfaces 81a, 82a allows preventing the sticking. Otherwise, primarily the surfaces 81a, 82a may be subjected to water-repellent silylation coating after the etching process described referring to FIG. 14(d), to avoid the sticking.

The foregoing measures, however, may be unsuitable for example if the surfaces 81a, 82a are excessively large, because in such case it is difficult to adequately roughen or coat the opposing surfaces 81a, 82a. Besides, whereas the foregoing measures are additionally performed after completing the fabrication of the respective portions of the micro movable device X2, performing such additional process is undesirable from the viewpoint of the yield from the manufacturing of the micro movable device X2.

### SUMMARY OF THE INVENTION

The present invention has been proposed under the circumstances described above. It is therefore an object of the present invention to provide a micro movable device configured to prevent sticking and manufacturable with a high yield rate. Other objects of the present invention are to provide a wafer used for manufacturing such a micro movable device, and to provide a method of manufacturing such a wafer.

A first aspect the present invention provides a micro movable device. The micro movable device is obtained by processing a material substrate of a multilayer structure including a first layer, a second layer having a finely rough region on its surface on the side of the first layer, and an intermediate layer provided between the first layer and the second layer. The micro movable device includes a first structure formed in the first layer, and a second structure formed in the second layer, where the second structure includes a portion opposing the first structure via a gap and having a finely rough region on the side of the first structure. The second structure is displaceable relative to the first structure (for example, moving toward and away from the first structure). The micro movable device may serve as part of an angular speed sensor or an acceleration sensor.

The first structure of the micro movable device is formed in the first layer, for example by performing an anisotropic dry etching process over the first layer so as to partially expose the intermediate layer of the material substrate having the foregoing multilayer structure. The second structure is formed in the second layer, for example by performing an anisotropic dry etching process over the second layer. Then, performing for example an isotropic wet etching, so as to remove a portion of the intermediate layer located between the first and the second structure, can cause the first structure and the second structure to oppose each other via a gap. The surface of the second structure on the side of the first structure is a part of the finely rough region on the first layer side, of the second layer, formerly a part of the material substrate, and hence has a finely rough structure. Because of such finely rough region provided on the second structure, the first structure and the second structure are prevented from accidentally sticking to each other, in this micro movable device.

Moreover, the finely rough structure which serves to prevent the sticking is already present prior to forming the first and the second structure in the manufacturing process of the micro movable device, which eliminates the need to perform an etching process or a coating process for inhibiting the sticking, after forming at least one of the first structure and the second structure. Such arrangement is advantageous for manufacturing the micro movable device with higher yield.

Thus, the micro movable device according to the first aspect of the present invention is appropriate for preventing the sticking between the first and the second structure, as well as for manufacturing with higher yield.

A second aspect of the present invention provides a wafer. The wafer has a multilayer structure including a first layer, a second layer having a finely rough region on the side of the first layer, and an intermediate layer provided between the first and the second layer. Such wafer may be employed as the material substrate for manufacturing the micro movable device according to the first aspect.

In the first and the second aspect of the present invention, it is preferable that the finely rough region on the second layer is provided by depositing one of polysilicon and amorphous silicon on the second layer, or performing an etching process over the surface of the second layer. These methods allow forming an appropriate finely rough structure on the second layer for preventing the sticking. The surface roughness of the finely rough region of the second layer is, for example, not less than 10 nm, and not exceeding 20% of the thickness of the intermediate layer.

A third aspect of the present invention provides a method of manufacturing a wafer having a multilayer structure including a first layer, a second layer having a finely rough region on the side of the first layer, and an intermediate layer provided between the first and the second layer. The method includes depositing polysilicon or amorphous silicon over a surface of a pre-second layer, or performing an etching process over the surface of the pre-second layer, thereby forming the finely rough region. Then, a pre-intermediate layer is formed over the finely rough region of the pre-second layer. The pre-second layer and the pre-first layer are joined to each other via the pre-intermediate layer formed over the finely rough region.

A fourth aspect of the present invention provides another method of manufacturing a wafer having a multilayer structure including a first layer, a second layer having a finely rough region on the side of the first layer, and an intermediate layer provided between the first and the second layer. The method includes depositing polysilicon or amorphous silicon over a surface of a pre-second layer, or performing an etching process over the surface of the pre-second layer, thereby forming the finely rough region. Then, a pre-intermediate layer is formed over the finely rough region of the pre-second layer. Then, the first layer is formed by depositing a material over the pre-intermediate layer

In the third and the fourth aspect of the present invention, preferably the pre-intermediate layer may be an insulating layer such as a silicon oxide layer, a silicon nitride layer, or an alumina layer.

### BRIEF DESCRIPTION OF THE DRAWINGS

FIG. 1 is a fragmentary plan view showing a gyro sensor according to the present invention;

FIG. 2 is another fragmentary plan view showing the gyro sensor according to the present invention;

FIG. 3 is a cross-sectional view taken along a line III-III in FIG. 1;

FIG. 4 is a cross-sectional view taken along a line IV-IV in FIG. 1;

FIG. 5 is a cross-sectional view taken along a line V-V in FIG. 1;

FIG. 6 is a cross-sectional view taken along a line VI-VI in FIG. 1;

FIG. 7 is a cross-sectional view taken along a line VII-VII in FIG. 1;

FIG. 8 is a cross-sectional view taken along a line VIII-VIII in FIG. 1;

FIG. 9 shows in section some steps of a manufacturing process of the gyro sensor shown in FIG. 1;

FIG. 10 shows some steps of the manufacturing process which are subsequent to those shown in FIG. 9;

FIG. 11 shows some steps of the manufacturing process which are subsequent to those shown in FIG. 10;

FIG. 12 shows a manufacturing process of another wafer;

FIG. 13 is a cross-sectional view illustrating a conventional micro movable device;

FIG. 14 shows in section some steps of a manufacturing process of the micro movable device shown in FIG. 13; and

FIG. 15 is a sectional view illustrating the sticking of the micro movable device shown in FIG. 13.

### DETAILED DESCRIPTION OF THE PREFERRED EMBODIMENTS

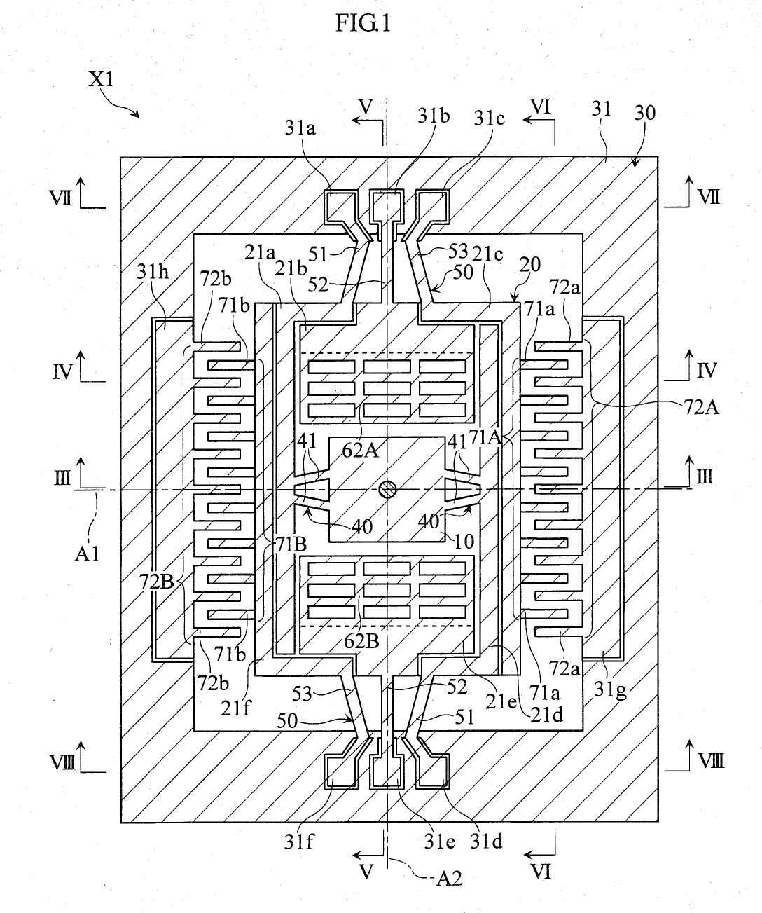

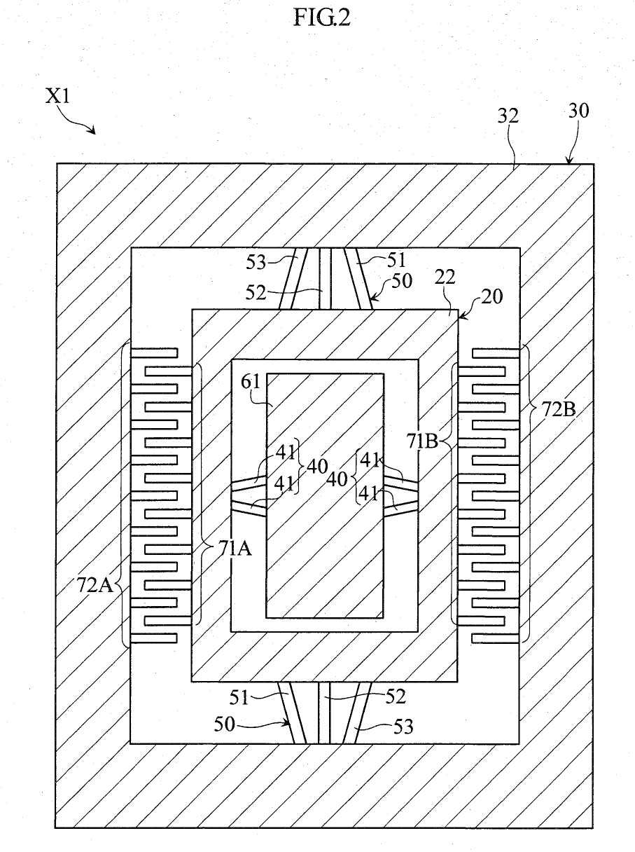

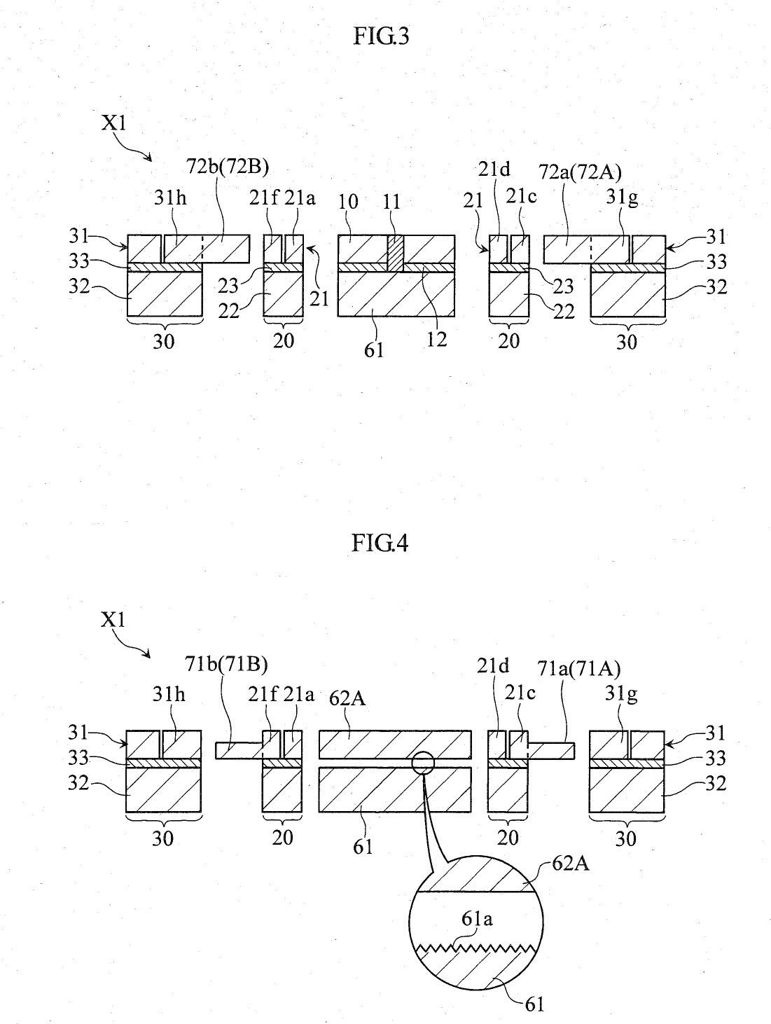

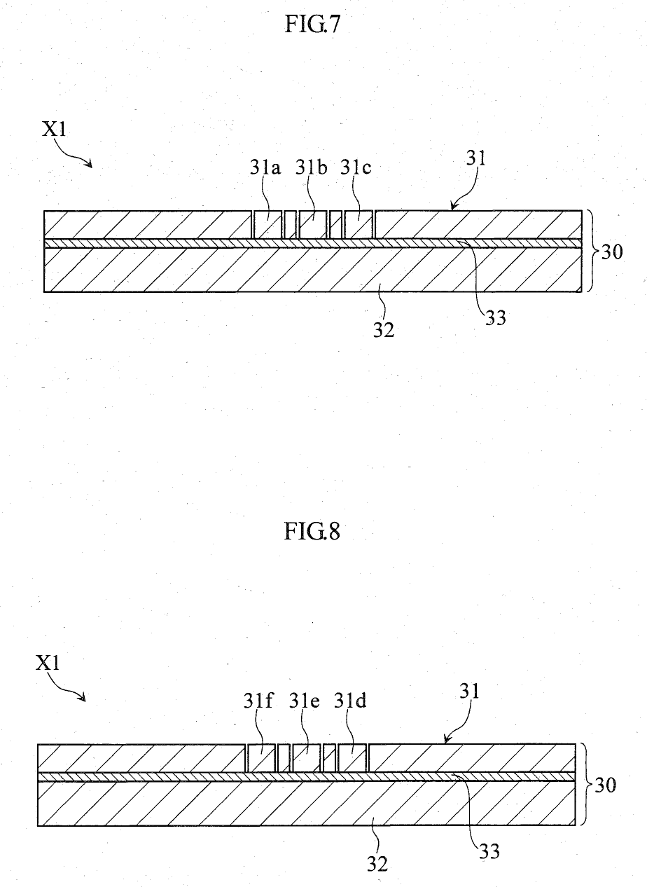

FIGS. 1 to 8 illustrate a gyro sensor X1 according to the present invention. FIG. 1 is a fragmentary plan view of the gyro sensor X1, and FIG. 2 is another fragmentary plan view of the gyro sensor X1. FIGS. 3 to 8 are cross-sectional views taken along lines III-III, IV-IV, V-V, VI-VI, VII-VII, and VIII-VIII in FIG. 1, respectively.

The gyro sensor X1 includes a land portion 10, an inner frame 20, an outer frame 30, a pair of link portions 40, a pair of link portions 50, a detecting electrode 61 (not shown in FIG. 1), detecting electrodes 62A, 62B (not shown in FIG. 2), and driving electrodes 71A, 71B, 72A, 72B, and serves as an angular speed sensor. The gyro sensor X1 is of a type to be manufactured by processing a wafer, which is so called a SOI substrate, with use of a bulk micromachining technique such as MEMS technique. The wafer has a multilayer structure including, for example, a first and a second silicon layers, and an insulating layer provided between the silicon layers, which are given a predetermined conductivity by doping impurity. Hatched sections in FIG. 1 indicate portions derived from the first silicon layer and located closer to the viewer than the insulating layer, and hatched sections in FIG. 2 indicate portions derived from the second silicon layer and located closer to the viewer than the insulating layer.

The land portion 10 is a portion derived from the first silicon layer. As shown in FIGS. 3 and 5, the land portion 10 includes a conductive plug 11 buried therein.

The inner frame 20 has, as shown in FIG. 3 for example, a multilayer structure including a first layer portion 21 derived from the first silicon layer, a second layer portion 22 derived from the second silicon layer, and an insulating layer 23 provided therebetween. The first layer portion 21 includes segments 21a, 21b, 21c, 21d, 21e, 21f, as shown in FIG. 1. The segments 21a to 21f are separated from each other by a gap.

The outer frame 30 has, as shown in FIGS. 3 and 4 for example, a multilayer structure including a first layer portion 31 derived from the first silicon layer, a second layer portion 32 derived from the second silicon layer, and an insulating layer 33 provided therebetween. The first layer portion 31 includes segments 31a, 31b, 31c, 31d, 31e, 31f, 31g, 31h, as shown in FIG. 1. The segments 31a to 31h are separated from each other by a gap, and constitute a terminal portion in the gyro sensor X1 for external connection.

The pair of link portions 40 serves to connect the land portion 10 and the inner frame 20, and is derived from the first silicon layer. Each link portion 40 includes two torsion bars 41. As shown in FIG. 1, the respective torsion bars 41 of one of the link portions 40 are connected to the land portion 10 and to the segment 21a of the first layer portion 21 of the inner frame 20, so as to electrically connect the land portion 10 and the segment 21a. The respective torsion bars 41 of the other link portion 40 are connected to the land portion 10 and to the segment 21d of the first layer portion 21 of the inner frame 20, so as to electrically connect the land portion 10 and the segment 21d. The pair of link portions 40 thus configured defines an axial center A1 of the oscillating motion of the land portion 10. Each link portion 40, which includes the two torsion bars 41 defining therebetween a space gradually increasing from the inner frame 20 toward the land portion 10 is advantageous for suppressing an unnecessary displacement component in the oscillating motion of the land portion 10.

The pair of link portions 50 serves to connect the inner frame 20 and the outer frame 30, and is derived from the first silicon layer. Each link portion 50 includes three torsion bars 51, 52, 53. As shown in FIG. 1, the torsion bar 51 of one of the link portions 50 is connected to the segment 21a of the first layer portion 21 of the inner frame 20 and to the segment 31a of the first layer portion 31 of the outer frame 30, so as to electrically connect the segment 21a and the segment 31a. The torsion bar 52 is connected to the segment 21b of the first layer portion 21 of the inner frame 20 and to the segment 31b of the first layer portion 31 of the outer frame 30, so as to electrically connect the segment 21b and the segment 31b. The torsion bar 53 is connected to the segment 21c of the first layer portion 21 of the inner frame 20 and to the segment 31c of the first layer portion 31 of the outer frame 30, so as to electrically connect the segment 21c and the segment 31c. The torsion bar 51 of the other link portions 50 is connected to the segment 21d of the first layer portion 21 of the inner frame 20 and to the segment 31d of the first layer portion 31 of the outer frame 30, so as to electrically connect the segment 21d and the segment 31d. The torsion bar 52 is connected to the segment 21e of the first layer portion 21 of the inner frame 20 and to the segment 31e of the first layer portion 31 of the outer frame 30, so as to electrically connect the segment 21e and the segment 31e. The torsion bar 53 is connected to the segment 21f of the first layer portion 21 of the inner frame 20 and to the segment 31f of the first layer portion 31 of the outer frame 30, so as to electrically connect the segment 21f and the segment 31f. The pair of link portions 50 thus configured defines an axial center A2 of the oscillating motion of the inner frame 20. Each link portion 50, which includes the two torsion bars 51, 53 defining therebetween a space gradually increasing from the outer frame 30 toward the inner frame 20 is advantageous for suppressing emergence of an unnecessary displacement component in the oscillating motion of the inner frame 20.

The detecting electrode 61 is a portion derived from the second silicon layer, and corresponds to the second structure according to the present invention. The detecting electrode 61 includes a finely rough region 61a, for example as shown in FIGS. 4 and 5 in an enlarged scale. The surface roughness (Rz) of the finely rough region 61a is, for example, 10 to 200 nm. Referring also to FIGS. 3 and 5, the detecting electrode 61 is joined to the land portion 10 via the insulating layer portion 12 derived from the insulating layer, and is electrically connected to the land portion 10 via the conductive plug 11 provided so as to penetrate through the land portion 10 and the insulating layer portion 12.

The detecting electrode 62A is a portion derived from the first silicon layer, and corresponds to the first structure according to the present invention. As shown in FIG. 5, the detecting electrode 62A includes a portion extending from the segment 21b of the first layer portion 21 of the inner frame 20 toward the land portion 10, so as to oppose the detecting electrode 61. The detecting electrode 62A includes a plurality of openings.

The detecting electrode 62B is a portion derived from the first silicon layer, and corresponds to the first structure according to the present invention. As shown in FIG. 5, the detecting electrode 62B includes a portion extending from the segment 21e of the first layer portion 21 of the inner frame 20 toward the land portion 10, so as to oppose the detecting electrode 61. The detecting electrode 62B includes a plurality of openings.

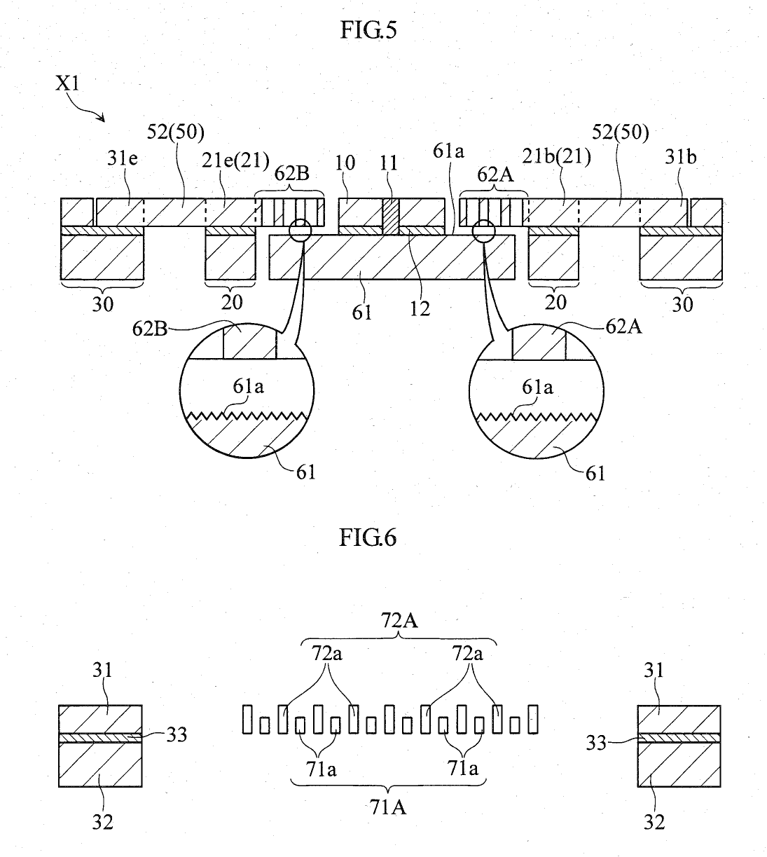

The driving electrode 71A is a combtooth-like electrode derived from the first silicon layer, and includes a plurality of electrode teeth 71a extending from the segment 21c of the inner frame 20, as shown in FIG. 1. The electrode teeth 71a are parallel to each other, for example as shown in FIGS. 1 and 6.

The driving electrode 71B is a combtooth-like electrode derived from the first silicon layer, and includes a plurality of electrode teeth 71b extending from the segment 21f of the inner frame 20. The electrode teeth 71b are parallel to each other.

The driving electrode 72A is a combtooth-like electrode derived from the first silicon layer, and located so as to oppose the driving electrode 71A. The driving electrode 72A includes a plurality of electrode teeth 72a extending from the segment 31g of the outer frame 30. The electrode teeth 72a are parallel to each other, for example as shown in FIGS. 1 and 6, and also parallel to the electrode teeth 71a of the driving electrode 71A.

The driving electrode 72B is a combtooth-like electrode derived from the first silicon layer, and located so as to oppose the driving electrode 71B. The driving electrode 72B includes a plurality of electrode teeth 72b extending from the segment 31h of the outer frame 30. The electrode teeth 72b are parallel to each other, and also parallel to the electrode teeth 71b of the driving electrode 71B.

When the gyro sensor X1 is driven, the movable portion (land portion 10, inner frame 20, driving electrodes 61, 62A, 62B) is caused to oscillate about the axial center A2 at a predetermined frequency or cycle. Such oscillating motion is achieved by alternately and repeatedly applying a voltage between the driving electrodes 71A, 72A and between the driving electrodes 71B, 72B. For this operation, the potential can be given to the driving electrode 71A through the segment 31c of the outer frame 30, the torsion bar 53 of one of the link portions 50, and the segment 21c of the inner frame 20. The potential can be given to the driving electrode 71B through the segment 31f of the outer frame 30, the torsion bar 53 of the other link portion 50, and the segment 21f of the inner frame 20. The potential can be given to the driving electrode 72A through the segment 31g of the outer frame 30. The potential can be given to the driving electrode 72B through the segment 31h of the outer frame 30. In this embodiment, for example alternately and repeatedly giving the potential to the driving electrode 72A and to the driving electrode 72B, with the driving electrodes 71A, 71B being grounded, can cause the movable portion to oscillate.

When a predetermined angular speed or acceleration acts on the gyro sensor X1, hence on the movable portion while the movable portion is being caused to oscillate or vibrate as described above for example, the land portion 10 is rotationally displaced about the axial center A1 together with the driving electrode 61, to a predetermined extent, so as to change the gap volume between a portion of the detecting electrode 61 opposing the detecting electrode 62A and the detecting electrode 62A, as well as the gap volume between a portion of the detecting electrode 61 opposing the detecting electrode 62B and the detecting electrode 62B (the detecting electrode 61 and the detecting electrodes 62A, 62B can relatively move toward or away from each other). The change in volume of those gaps incurs a change in static capacitance between the detecting electrodes 61, 62A, as well as between the detecting electrodes 61, 62B. The amount of the rotational displacement of the land portion 10 and the driving electrode 61 can be detected based on the change in static capacitance between the detecting electrodes 61, 62A, and between the detecting electrodes 61, 62B. Then the detection result thus obtained serves for calculation of the angular speed or acceleration acting on the movable portion, or on the gyro sensor X1.

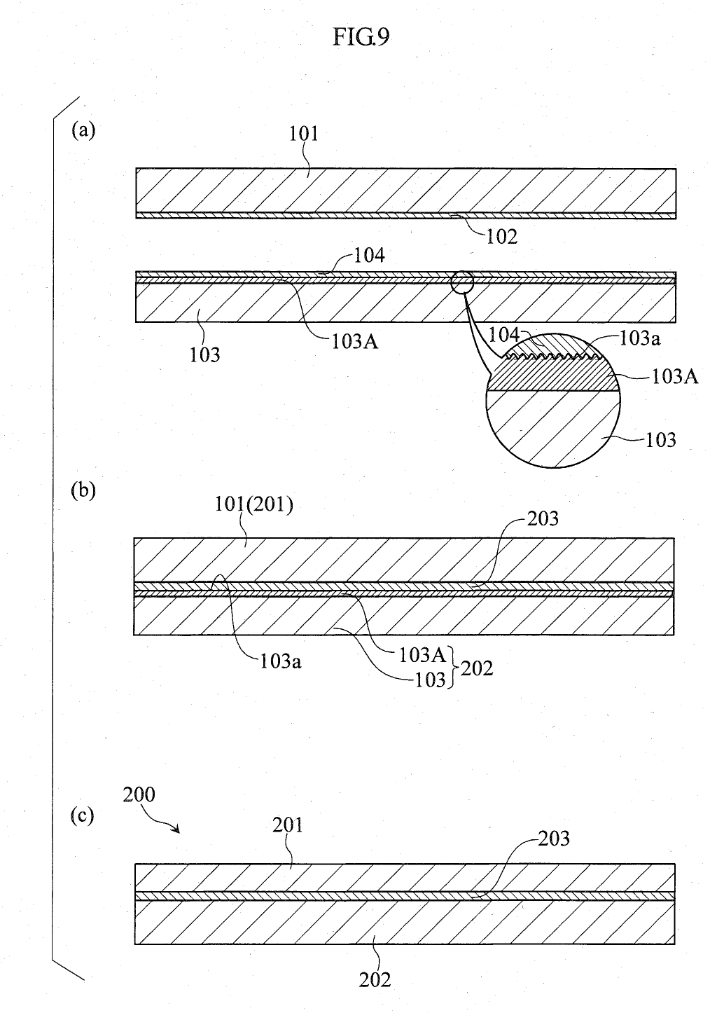

FIGS. 9 to 11 illustrate a method of manufacturing the gyro sensor X1. The method represents an example of application of a micromachining technique to the manufacturing of the gyro sensor X1. FIGS. 9(a) to 11(d) sequentially illustrate the forming process of a land portion L, frames F1, F2, link portions C1, C2, and electrodes E1, E2, E3, E4 shown in FIG. 11(d), in a form of changes in profile of a certain cross-section. Such certain cross-section is a schematically expressed model of a cross-section of one of a plurality of predetermined portions included in a single fabrication section of the gyro sensor, in a wafer being subjected to processing. The land portion L corresponds to a portion of the land portion 10. The frame F1 corresponds to the inner frame 20, and represents a transverse cross-section of a predetermined position of the inner frame 20. The frame F2 respectively corresponds to the outer frame 30, and represents a transverse cross-section of a predetermined position of the outer frame 30. The link portion C1 corresponds to the link portion 40, and represents a transverse cross-section of the torsion bar 41. The link portion C2 corresponds to the link portion 50, and represents a vertical cross-section of one of the torsion bars 51, 52, 53. The electrode E1 corresponds to a portion of the driving electrode 61. The electrode E2 corresponds to the driving electrodes 62A, 62B. The electrode E3 corresponds to the detecting electrodes 71A, 71B. The electrode E4 corresponds to the detecting electrode 72A, 72B.

To manufacture the gyro sensor X1, first, an insulating layer 102 is formed on a wafer 101 on one hand, and on the other hand a surface-roughened layer 103A and an insulating layer 104 are sequentially formed on a wafer 103, as shown in FIG. 9(a).

The wafer 101 corresponds to the pre-first layer according to the present invention, and is constituted of, for example, a silicon material doped with impurity for giving conductivity. Suitable examples of the impurity include a p-type impurity such as B, and an n-type impurity such as P and Sb. The insulating layer 102 may be constituted of a silicon oxide layer, a silicon nitride layer, or an alumina layer. The insulating layer 102 can be formed through depositing a predetermined material on the wafer 101, for example by a CVD or sputtering process.

The wafer 103 corresponds to the pre-second layer according to the present invention, and is constituted of, for example, a silicon material doped with impurity for giving conductivity. Suitable examples of the impurity include a p-type impurity such as B, and an n-type impurity such as P and Sb. The surface-roughened layer 103A is constituted of polysilicon or amorphous silicon for example, and includes a finely rough region 103a. The wafer 103 has a thickness of, for example, 100 to 525 μm. The surface-roughened layer 103A has a thickness of 1 to 2 μm for example, and the surface roughness (Rz) of the finely rough region 103a is preferably 10 nm or more, for example 10 to 200 nm. The surface-roughened layer 103A can be formed through depositing polysilicon or amorphous silicon on the wafer 103, for example by a CVD process. The insulating layer 104 may be formed from the same material and through the same process, as those for the insulating layer 102.

Referring then to FIG. 9(b), the wafers 101, 103 subjected to the foregoing process are joined. Examples of the joining method include so-called direct bonding and room-temperature bonding. This process provides a multilayer structure including a silicon layer 201 derived from the wafer 101, a silicon layer 202 derived from the wafer 103 and the surface-roughened layer 103A, and including the finely rough region 103a, and an insulating layer 203 formed upon bonding the insulating layers 102, 104. The insulating layer 203 has a thickness of 1 to 2 μm, for example. It is preferable that the surface roughness Rz of the finely rough region 103a is 20% or less of the thickness of the insulating layer 203.

Then as shown in FIG. 9(c), a polishing process is performed so as to reduce the thickness of the silicon layer 201. In this case, for example a CMP process may be adopted. After this process, the thickness of the silicon layer 201 becomes 10 to 100 μm, for example. Through the series of steps shown in FIGS. 9(a) to 9(c), a SOI wafer 200 can be obtained.

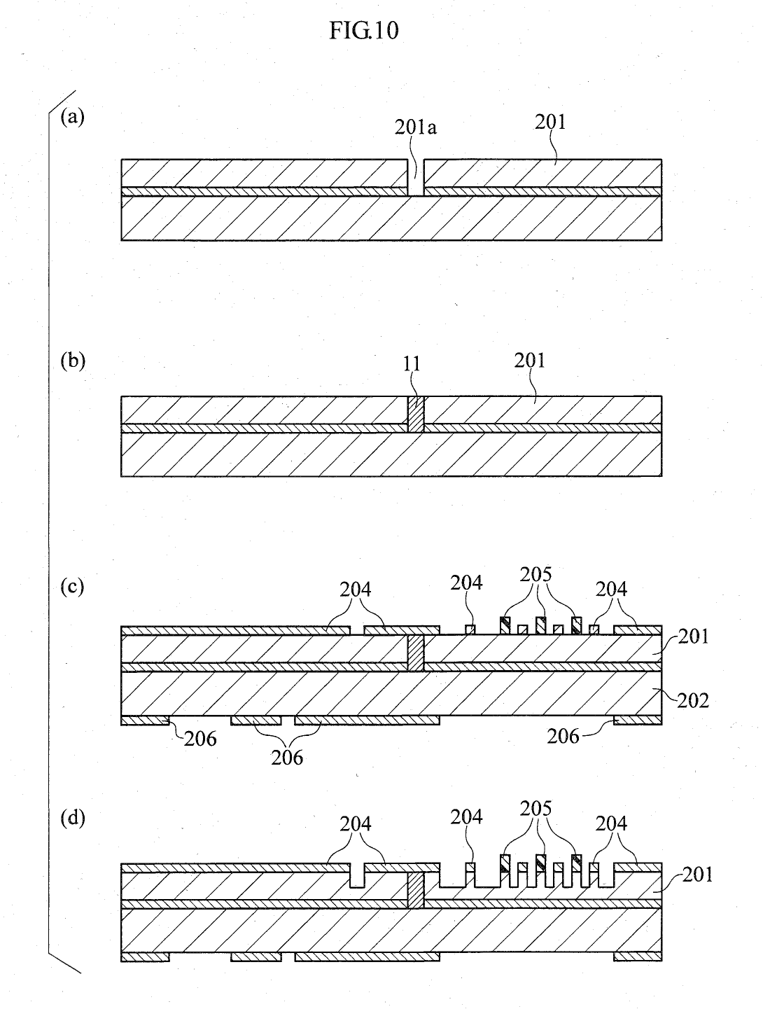

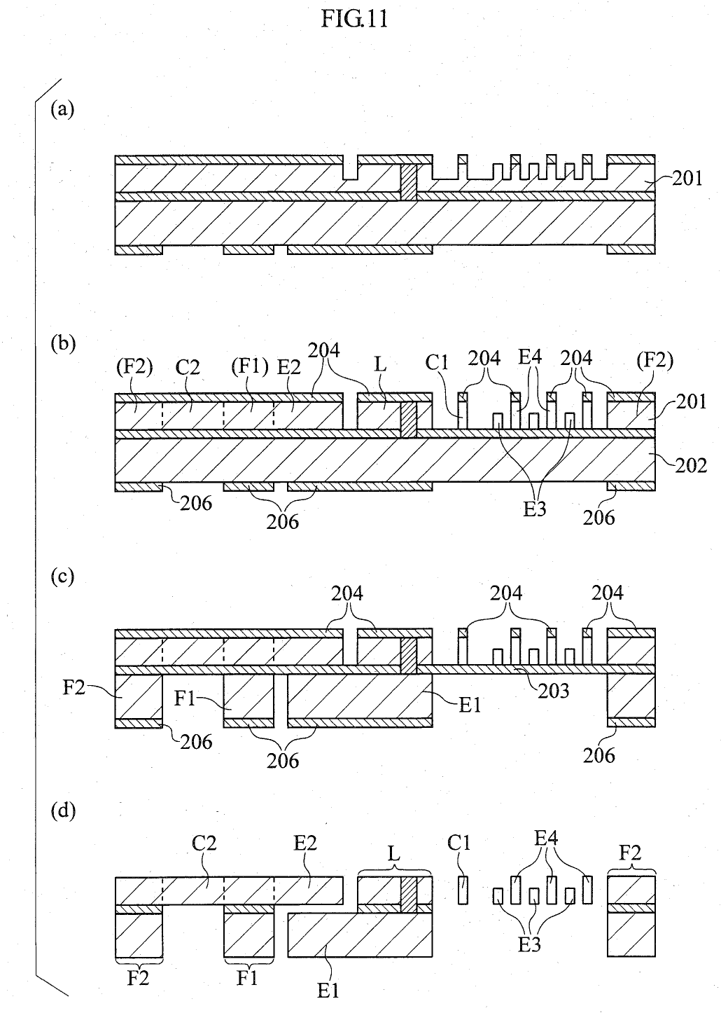

Proceeding to FIG. 10(a), a through-hole 201a is formed so as to penetrate through the silicon layer 201 and the insulating layer 203. More specifically, after forming a resist pattern (not shown) with a predetermined opening on the silicon layer 201, a deep reactive ion etching (hereinafter, DRIE) process is performed utilizing the resist pattern as the mask, thereby performing an anisotropic dry etching process over the silicon layer 201 until the insulating layer 203 is partially exposed. The DRIE process facilitates properly performing the anisotropic dry etching, in a Bosch process of alternately executing the etching and protection of the sidewall. For this and subsequent DRIE process, the Bosch process may be adopted. Then the exposed portion of the insulating layer 203 is removed by a different etching process (for example, wet etching utilizing buffered hydrofluoric acid (hereinafter, BHF) composed of fluoric acid and ammonium fluoride). Thus, the through-hole 201a can be obtained.

Referring to FIG. 10(b), the conductive plug 11 is formed. In this case, filling the through-hole 201a with a conductive material provides the conductive plug 11.

Referring then to FIG. 10(c), an oxide layer pattern 204 and a resist pattern 205 are formed on the silicon layer 201, and an oxide layer pattern 206 is formed on the silicon layer 202. The oxide layer pattern 204 has a pattern shape corresponding to the land portion L, the frames F1, F2, the link portions C1, C2, and the electrodes E2, E4. The resist pattern 205 has a pattern shape corresponding to the electrode E3. The oxide layer pattern 206 has a pattern shape corresponding to the frames F1, F2 and the electrode E1.

To form the oxide layer pattern 204, first a CVD process is performed so as to deposit silicon oxide on the surface of the silicon layer 201, until the thickness reaches, for example, 1 μm. Then an etching process is performed with a predetermined resist pattern serving as the mask, so as to shape the oxide layer on the silicon layer 201 into the predetermined pattern. The oxide layer pattern 206 may also be formed on the silicon layer 202 through depositing an oxide material and forming a resist pattern on the oxide layer, followed by the etching process. On the other hand, to form the resist pattern 205, a predetermined liquid photoresist is first deposited on the silicon layer 201 by spin-coating. Then after the exposure and development process, the photoresist is patterned.

Proceeding to FIG. 10(d), the DRIE process is performed utilizing the oxide layer patterns 204, 205 as the mask, thereby performing the etching over the silicon layer 201 to a predetermined depth, thicknesswise of the silicon layer 201. Such depth corresponds to the height of the electrode E3 (driving electrodes 71A, 71B).

After removing the resist pattern 205 as shown in FIG. 11(a), the DRIE process is performed utilizing the oxide layer pattern 204 as the mask, thereby performing the etching over the silicon layer 201 as shown in FIG. 11(b). At this stage, the land portion L, a part of the frame F1, a part of the frame F2, the link portions C1, C2, and the electrodes E2, E3, E4 are obtained.

Then referring to FIG. 11(c), the DRIE process is performed utilizing the oxide layer pattern 206 as the mask, thereby performing the etching over the silicon layer 202. At this stage, the remaining part of the frames F1, F2 and the electrode E1 are obtained.

Referring finally to FIG. 11(d), exposed portions of the insulating layer 203, and the oxide layer patterns 204, 206 are removed by etching. Here, either a dry etching or wet etching may be performed. In the case of dry etching, for example CHF₃ may be employed as the etching gas. For wet etching, for example BHF may be employed as the etching solution.

Throughout the foregoing steps, the land portion L, the frames F1, F2, the link portions C1, C2, and the electrodes E1 to E4 are formed, and the gyro sensor X1 can be obtained.

The surface of the detecting electrode 61 (finely rough region 61a) in the gyro sensor X1, on the side of the detecting electrode 62A, 62B, for example shown in FIG. 5, is a part of the finely rough region 103a of the silicon layer 202, formerly a part of the SOI wafer 200, and has the finely rough structure. Because of the finely rough region 61a provided on the detecting electrode 61, the detecting electrode 61 and the detecting electrodes 62A, 62B are prevented from accidentally sticking to each other, in the gyro sensor X1.

Moreover, the finely rough structure which serves to prevent the sticking is already present prior to forming the detecting electrodes 61 and the detecting electrodes 62A, 62B in the manufacturing process of the gyro sensor X1, which eliminates the need to perform an etching process or a coating process for inhibiting the sticking, after forming at least one of the detecting electrode 61 and the detecting electrodes 62A, 62B. The gyro sensor X1 thus configured is appropriate for manufacturing with higher yield.

Thus, the gyro sensor X1 according to the present invention is appropriate for preventing the sticking between the detecting electrode 61 and the detecting electrodes 62A, 62B, as well as for manufacturing with higher yield.

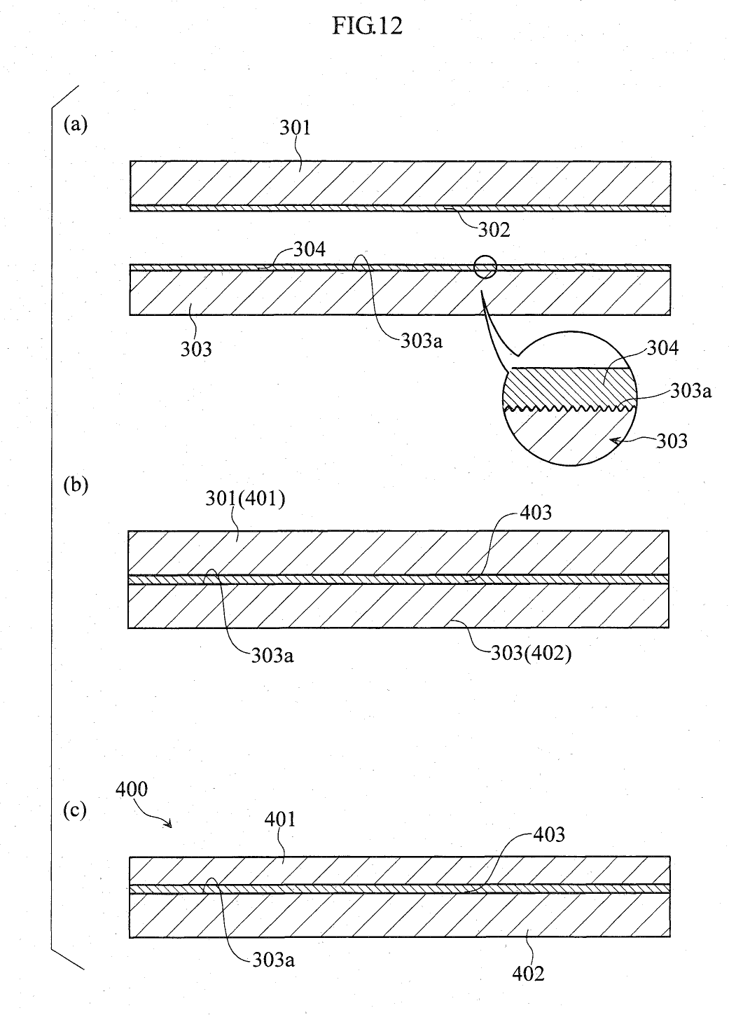

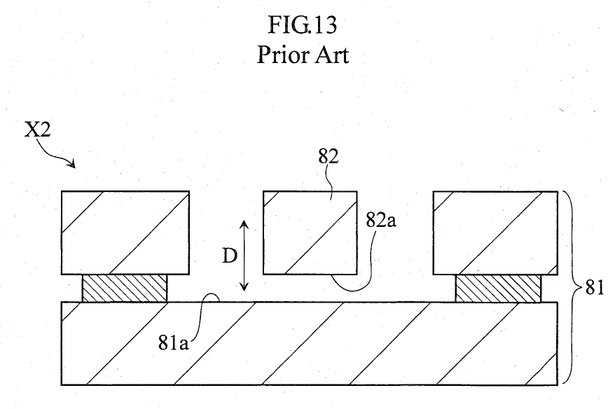

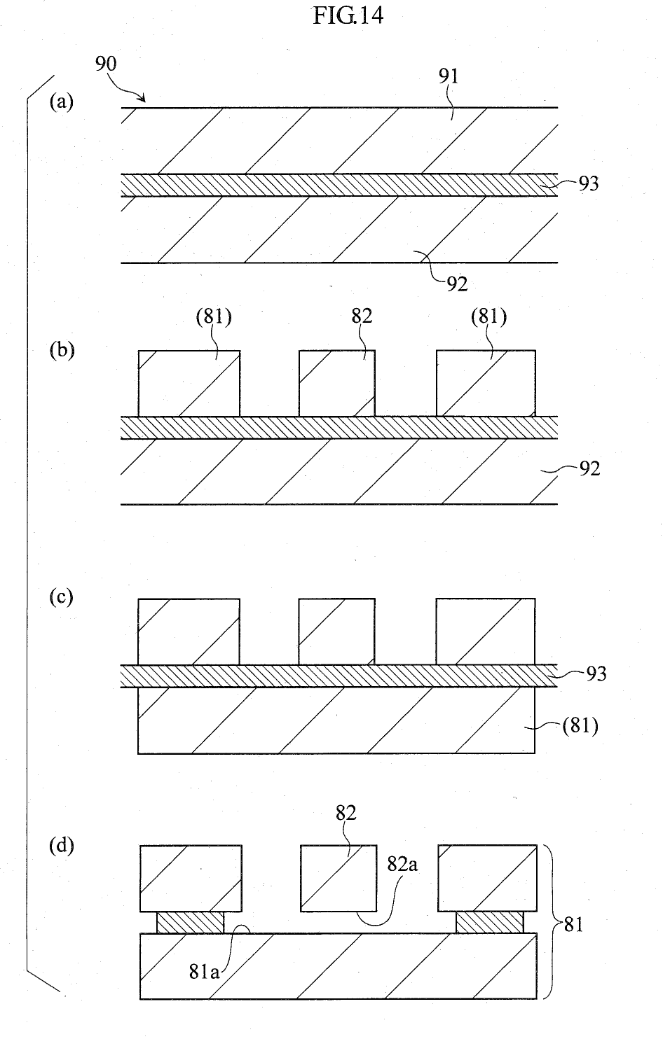

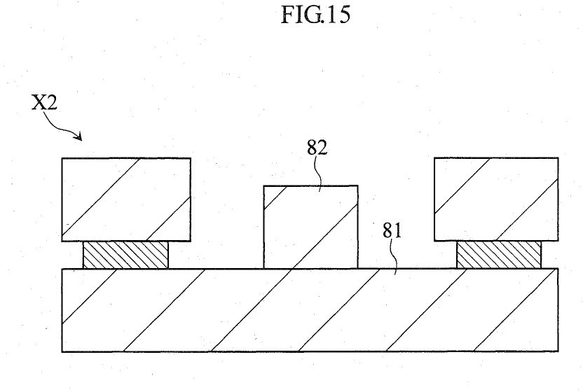

FIG. 12 illustrates a method of manufacturing a SOI wafer that can be substituted with the foregoing SOI wafer 200, in the manufacturing process of the gyro sensor X1.

Referring first to 12(a), an insulating layer 302 is formed on a wafer 301 on one hand, and on the other hand a finely rough region 303a is formed on a wafer 303, after which an insulating layer 304 is formed on the finely rough region 303a.

The wafer 301 corresponds to the pre-first layer according to the present invention, and is constituted of, for example, a silicon material doped with an impurity for giving conductivity. Suitable examples of the impurity include a p-type impurity such as B, and an n-type impurity such as P and Sb. The insulating layer 102 may be constituted of a silicon oxide layer, a silicon nitride layer, or an alumina layer. The insulating layer 302 may be formed from the same material and through the same process, as those for the foregoing insulating layer 102.

The wafer 303 corresponds to the pre-second layer according to the present invention, and is constituted of, for example, a silicon material doped with an impurity for giving conductivity. The finely rough region 303a may be formed through performing an etching process over the surface of the wafer 303. In this case, an isotropic dry etching process that employs SF₆ as the etching gas, or a wet etching process that employs a mixture of fluoronitric acid and acetic acid as the etching solution may be performed. The surface roughness (Rz) of the finely rough region 303a is preferably 10 nm or more, for example 10 to 200 nm. The insulating layer 304 may be formed from the same material and through the same process, as those for the insulating layer 102.

Then referring to FIG. 12(b), the wafers 301, 303 subjected to the foregoing process are joined. Examples of the joining method include so-called direct bonding and room-temperature bonding. This process provides a multilayer structure including a silicon layer 401 derived from the wafer 301, a silicon layer 402 derived from the wafer 303 and having the finely rough region 303a, and an insulating layer 403 formed upon bonding the insulating layers 302, 304. The insulating layer 403 has a thickness of 1 to 2 μm, for example. It is preferable that the surface roughness Rz of the finely rough region 303a is 20% or less of the thickness of the insulating layer 403.

Proceeding to FIG. 12(c), a polishing process is performed so as to reduce the thickness of the silicon layer 401. In this case, for example a CMP process may be adopted. After this process, the thickness of the silicon layer 401 becomes 10 to 100 μm, for example. Throughout the series of steps shown in FIGS. 12(a) to 12(c), a SOI wafer 400 can be obtained. Substituting the SOI wafer 200 with the SOI wafer 400 in the manufacturing process described referring to FIGS. 10(a) to 11(d) can equally provide the gyro sensor X1.

The wafer employed for manufacturing the gyro sensor X1 can also be obtained through depositing a predetermined material on the wafer 103 provided with the surface-roughened layer 103A and the insulating layer 104 as shown in FIG. 9(a). In this case, for example, the insulating layer 104 may be formed with a sufficient thickness on the surface-roughened layer 103A, and then polished for planarization by CMP or the like, after which a polysilicon material such as Poly-Si or Poly-SiGe may be deposited on the insulating layer 104 so as to reach a predetermined thickness.

The wafer employed for manufacturing the gyro sensor X1 can also be obtained through depositing a predetermined material on the wafer 303 including the finely rough region 303a and provided with the insulating layer 304 as shown in FIG. 12(a). In this case, for example, the insulating layer 304 may be formed with a sufficient thickness on the finely rough region 303a, and then polished for planarization by CMP or the like, after which a polysilicon material such as Poly-Si or Poly-SiGe may be deposited on the insulating layer 304 so as to reach a predetermined thickness.

1. A micro movable device obtained by processing a material substrate of a multilayer structure including a first layer, a second layer having a finely rough region on a surface thereof on the side of the first layer, and an intermediate layer provided between the first layer and the second layer, the micro movable device comprising:
a first structure formed in the first layer; and
a second structure formed in the second layer and displaceable relative to the first structure, the second structure including a portion that faces the first structure via a gap and has a finely rough region on a side of the first structure.

2. The micro movable device according to claim 1, wherein the finely rough region is provided by depositing polysilicon or amorphous silicon on the second layer, or provided by etching the surface of the second layer.

3. The micro movable device according to claim 1, wherein a surface roughness of the finely rough region is not less than 10 nm, and not exceeding 20% of the thickness of the intermediate layer.

4. The micro movable device according to claim 1, configured as an angular speed sensor or an acceleration sensor.

5. A wafer comprising a multilayer structure including:
a first layer;
a second layer having a finely rough region on a side of the first layer; and
an intermediate layer provided between the first layer and the second layer.

6. The wafer according to claim 5, wherein the finely rough region is provided by depositing polysilicon or amorphous silicon on the second layer, or provided by etching a surface of the second layer.

7. The wafer according to claim 5, wherein a surface roughness of the finely rough region is not less than 10 nm, and not exceeding 20% of the thickness of the intermediate layer.

8. A method of manufacturing a wafer having a multilayer structure including a first layer, a second layer having a finely rough region on a side of the first layer, and an intermediate layer provided between the first layer and the second layer, the method comprising:
forming the finely rough region by depositing polysilicon or amorphous silicon over a surface of a pre-second layer or by etching the surface of the pre-second layer;
forming a pre-intermediate layer over the finely rough region of the pre-second layer; and
joining the pre-second layer and a pre-first layer via the pre-intermediate layer formed over the finely rough region.

9. The method according to claim 8, wherein the pre-intermediate layer is one of a silicon oxide layer, a silicon nitride layer and an alumina layer.

10. A method of manufacturing a wafer having a multilayer structure including a first layer, a second layer having a finely rough region on a side of the first layer, and an intermediate layer provided between the first layer and the second layer, the method comprising:
forming the finely rough region by depositing polysilicon or amorphous silicon over a surface of a pre-second layer or by etching the surface of the pre-second layer;
forming a pre-intermediate layer over the finely rough region of the pre-second layer; and
forming the first layer by depositing a material on the pre-intermediate layer.

11. The method according to claim 9, wherein the pre-intermediate layer is one of a silicon oxide layer, a silicon nitride layer, and an alumina layer.
